(19) United States
(12) Patent Application Publication
(10) Pub. No.: US 2022/0020603 A1
(43) Pub. Date: Jan. 20, 2022

(54) SHEET AND PROTECTIVE MEMBER FORMING METHOD

(71) Applicant: DISCO CORPORATION, Tokyo (JP)

(72) Inventors: Yoshinori KAKINUMA, Tokyo (JP); Yoshikuni MIGIYAMA, Tokyo (JP)

(21) Appl. No.: 17/378,974

(22) Filed: Jul. 19, 2021

(30) Foreign Application Priority Data
Jul. 20, 2020 (JP) 2020-123691

(51) Int. Cl. H01L 21/56; H01L 21/67

(52) U.S. Cl. CPC H01L 21/56; H01L 21/67126

(57) ABSTRACT

There is provided a sheet used at a time of formation of a protective member protecting one surface of a plate-shaped workpiece by spreading and curing a liquid resin on the one surface. The sheet includes a first layer configured to be brought into contact with a flat specular mounting surface, and a second layer configured to be brought into contact with the liquid resin. The first layer is formed of a material that is easily separated from the mounting surface after adhering to the mounting surface as compared with the second layer, and the second layer is formed of a material having high adhesiveness to the cured resin as compared with the first layer.

### BACKGROUND OF THE INVENTION

### Field of the Invention

The present invention relates to a sheet used at a time of formation of a protective member on a workpiece such as a semiconductor wafer and a protective member forming method using the sheet.

### Description of the Related Art

In forming a protective member on a wafer by using a protective member forming apparatus as disclosed in Japanese Patent Laid-Open No. 2017-168565 or Japanese Patent Laid-Open No. 2017-174883, in order to protect one surface of the wafer sliced from an ingot (what is generally called an as-sliced wafer), the protective member protecting one surface side of the wafer is formed by mounting a sheet on a mounting surface of a stage, supplying a liquid resin onto the sheet, spreading the liquid resin on one surface of the wafer, and then curing the liquid resin by application of an ultraviolet ray or the like.

In addition, a protective member forming apparatus disclosed in Japanese Patent Laid-Open No. 2020-024976 forms a protective member protecting one surface side of a wafer by affixing the wafer having a plurality of devices formed thereon to a tape affixed to a ring frame, mounting a sheet on the mounting surface of a stage, supplying a liquid resin onto the sheet, spreading the liquid resin by the wafer supported by the ring frame via the tape, and then curing the liquid resin. Then, after the protective member is formed, the sheet is separated from the stage, and the sheet is cut along the external shape of the wafer.

### SUMMARY OF THE INVENTION

In a case where a liquid resin having ultraviolet curability is used, for example, the stage is formed by glass, and after the liquid resin is spread by the wafer, the liquid resin is cured by irradiating the liquid resin with an ultraviolet ray from an ultraviolet irradiation lamp disposed below the glass stage. The sheet is heated by a heat of reaction at a time of the curing of the liquid resin. Therefore, when the sheet is to be separated from the glass stage together with the protective member after the liquid resin is cured, the sheet is difficult to separate because the sheet is softened by the heat of reaction and closely adheres to the upper surface of the glass stage. In addition, in a case where a sheet of a material that is easy to separate from the stage is used, the protective member formed of the cured resin is peeled off from the sheet and the wafer easily.

It is accordingly an object of the present invention to provide a sheet that is used at a time of formation of a protective member protecting one surface of a wafer and which can be easily separated from the mounting surface of a stage and prevents a protective member formed by a cured resin from being peeled off from the sheet and the wafer, and a protective member forming method using the sheet.

In accordance with an aspect of the present invention, there is provided a sheet used at a time of formation of a protective member protecting one surface of a plate-shaped workpiece by spreading and curing a liquid resin on the one surface. The sheet includes a first layer configured to be brought into contact with a flat specular mounting surface, and a second layer configured to be brought into contact with the liquid resin. The first layer is formed of a material that is easily separated from the mounting surface after adhering to the mounting surface as compared with the second layer, and the second layer is formed of a material having high adhesiveness to the cured resin as compared with the first layer.

Preferably, the first layer is formed of polyethylene terephthalate (PET), polyamide (PA), or polyimide (PI).

According to another aspect of the present invention, there is provided a protective member forming method using the sheet to form the protective member protecting the one surface of the workpiece. The protective member forming method includes a sheet mounting step of mounting the sheet onto the mounting surface such that the first layer is in contact with the mounting surface, a resin supply step of supplying the liquid resin to the second layer side of the sheet, and a protective member forming step of bonding and fixing the protective member in a plate shape, the protective member being formed by the resin in a cured state, to the one surface of the workpiece and the second layer of the sheet by curing the liquid resin after spreading the resin over the one surface of the workpiece by pressing the workpiece against the liquid resin supplied to the sheet.

A sheet according to one aspect of the present invention includes a first layer configured to be brought into contact with a flat specular mounting surface, and a second layer configured to be brought into contact with the liquid resin. The first layer is formed of a material that is easily separated from the mounting surface after adhering to the mounting surface as compared with the second layer, and the second layer is formed of a material having high adhesiveness to the cured resin as compared with the first layer. Thus, the protective member formed by the cured resin is not peeled off from the sheet, and the sheet is easily separated from the stage together with the formed protective member. Work efficiency can therefore be improved.

In addition, the protective member forming method according to another aspect of the present invention includes a sheet mounting step of mounting the sheet onto the mounting surface such that the first layer is in contact with the mounting surface, a resin supply step of supplying the liquid resin to the second layer side of the sheet, and a protective member forming step of bonding and fixing the protective member in a plate shape, the protective member being formed by the resin in a cured state, to the one surface of the workpiece and the second layer of the sheet by curing the liquid resin after spreading the resin over the one surface of the workpiece by pressing the workpiece against the liquid resin supplied to the sheet. Thus, the protective member formed by the cured resin is not peeled off from the sheet, and the sheet is easily separated from the stage together with the formed protective member. Work efficiency can therefore be improved.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating an example of a protective member forming apparatus;

FIG. 2 is a sectional view of assistance in explaining a holding unit, an expanding mechanism, a stage, a curing unit, and a liquid resin supply unit;

FIG. 3 is a sectional view of assistance in explaining a workpiece, a sheet, the holding unit, and the stage;

FIG. 4 is a sectional view of assistance in explaining a case of spreading a resin over a lower surface as one surface of the workpiece by pressing the workpiece onto the liquid resin supplied to the upper surface of the sheet, and thereafter curing the liquid resin by applying an external stimulus to the liquid resin, thus forming the resin into a plate shape, and bonding and fixing the resin to the lower surface of the workpiece and the upper surface of the sheet; and

FIG. 5 is an enlarged sectional view of assistance in explaining the case of spreading a resin over a lower surface as one surface of the workpiece by pressing the workpiece onto the liquid resin supplied to the upper surface of the sheet, and thereafter curing the liquid resin by applying an external stimulus to the liquid resin, thus forming the resin into a plate shape, and bonding and fixing the resin to the lower surface of the workpiece and the upper surface of the sheet.

### DETAILED DESCRIPTION OF THE PREFERRED EMBODIMENT

An embodiment according to one aspect of the present invention will hereinafter be described with reference to the accompanying drawings.

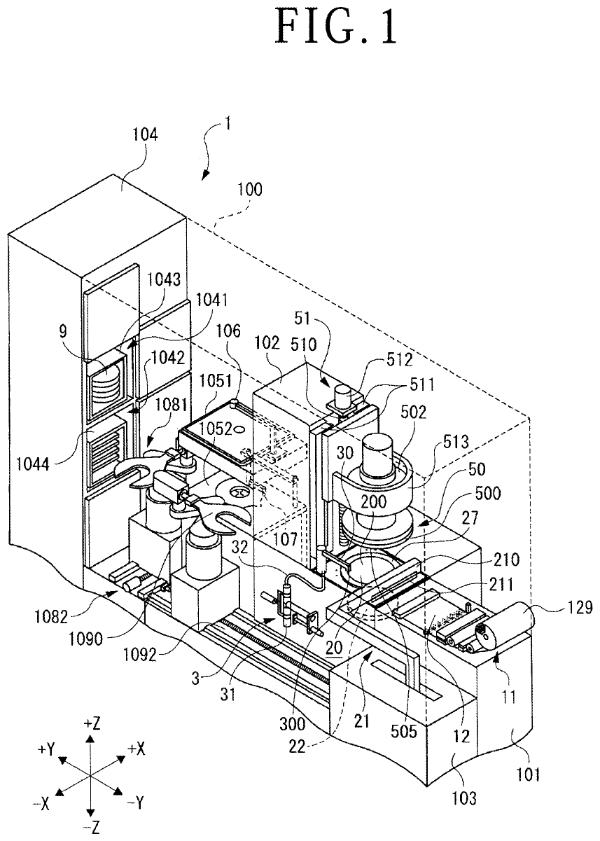

A protective member forming apparatus 1 illustrated in FIG. 1 is an example of an apparatus that forms a protective member on one surface of a plate-shaped workpiece. The protective member forming apparatus 1 includes a casing 100 that forms a processing chamber, an apparatus base 101 disposed within the casing 100, a column 102 erected on the apparatus base 101, a supporting base 103 disposed so as to adjoin a side surface of the apparatus base 101, and a cassette housing main body 104 coupled to the rear side (+Y direction side) of the casing 100 and having a housing space 1041 and a housing space 1042 in two stages in an upward-downward direction. A cassette 1043 that houses workpieces before formation of the protective member in a form of a plurality of shelves is disposed in the housing space 1041 as the upper stage. A cassette 1044 that houses the workpieces after the formation of the protective member in a form of a plurality of shelves is disposed in the housing space 1042 as a lower stage.

A workpiece on which the protective member is to be formed in the present embodiment is a work set 9 to be described in the following.

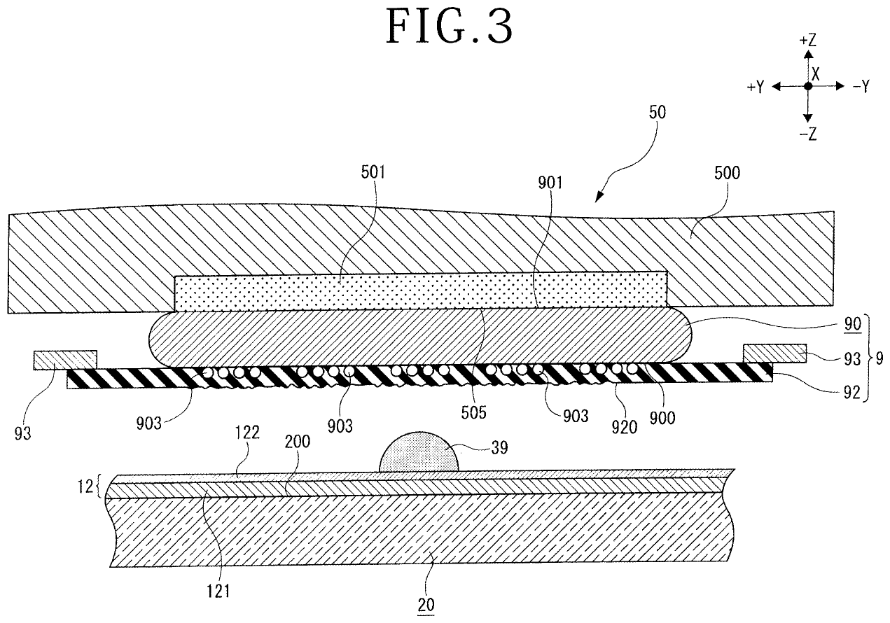

A semiconductor wafer 90 whose external shape is a circular plate shape, the semiconductor wafer 90 being illustrated in FIG. 3, is formed by a silicon wafer of a predetermined thickness, for example. Devices such as integrated circuits (ICs) or large scale integrations (LSIs) are formed in a plurality of regions demarcated by a plurality of planned dividing lines in a lattice form on a top surface 900 (lower surface in FIG. 3) of the semiconductor wafer 90. The surfaces of the devices are each provided with a plurality of bumps (protruding electrodes) 903. The bumps 903 formed of copper or the like, for example, have a height set at approximately a few ten μm.

The wafer 90 is, for example, in a state in which a circular tape 92 having a larger diameter than the wafer 90 is affixed to the top surface 900 of the wafer 90. In addition, an outer circumferential portion of the tape 92 is affixed to a ring frame 93. The work set 9 is thereby formed in which the wafer 90 is integrated with the ring frame 93 via the tape 92, and can be handled by the ring frame 93. In the following, the work set 9 will be referred to as a workpiece 9, the lower surface of the tape 92 will be referred to as one surface 920 of the workpiece 9 on which surface the protective member is to be formed, and an undersurface 901 of the wafer 90 will be referred to as another surface 901 held under suction by a holding unit 50.

Incidentally, the workpiece on which to form the protective member may be only the wafer 90. In this case, the protective member is directly formed on the top surface 900. That is, the top surface 900 is the one surface on which the protective member is to be formed.

The ring frame 93 is formed in the shape of an annular flat plate by a predetermined metal (for example, stainless steel (SUS) or the like) or a cured resin, and has a circular opening of an inside diameter larger than the outside diameter of the wafer 90. The wafer 90 is supported by the ring frame 93 via the tape 92 in a state in which the center of the wafer 90 and the center of the opening of the ring frame 93 substantially coincide with each other. The tape 92, for example, does not completely accommodate projections and depressions of the bumps 903, so that the one surface 920 of the tape 92 has projections and depressions formed in a region corresponding to the bumps 903. A polyethylene tape, for example, is used as the tape 92.

A first support 1051 and a second support 1052 located below the first support 1051 are coupled to a back surface on a +Y direction side of the column 102 illustrated in FIG. 1. The first support 1051 is provided with a wafer detecting unit 106 that detects a central position or the like of the workpiece 9 before formation of the protective member by using an imaged image. The second support 1052 is provided with a cutter (sheet cutter) 107 that cuts, along the external shape of the wafer 90, a part of the protective member and the like formed on the workpiece 9 which part extends off the wafer 90.

Disposed between the cassette housing main body 104 and the wafer detecting unit 106 and the cutter 107 is a first wafer transporting mechanism 1081 such as an articulated robot that loads and unloads the workpiece 9 into and from the cassette 1043 and the cassette 1044. The first wafer transporting mechanism 1081 can be reciprocated in an X-axis direction by an X-axis direction moving mechanism 1082 such as a ball screw mechanism. The first wafer transporting mechanism 1081 can unload the workpiece 9 before the formation of the protective member from the cassette 1043 and load the workpiece 9 onto the first support 1051, and unload the workpiece 9 on which the protective member is already formed from the second support 1052 and load the workpiece 9 into the cassette 1044.

The workpiece 9 whose central position or the like is detected by the wafer detecting unit 106 on the first support 1051 is held and transported by a second wafer transporting mechanism 1090 illustrated in FIG. 1 such as an articulated robot. The second wafer transporting mechanism 1090 has a holding hand that holds the workpiece 9 and is capable of swinging movement in a horizontal direction. The second wafer transporting mechanism 1090 can be reciprocated in a Y-axis direction by a Y-axis direction moving mechanism 1092 such as a ball screw mechanism. The second wafer transporting mechanism 1090 can unload the workpiece 9 from the first support 1051 and transfer the workpiece 9 to the holding unit 50.

Arranged on the apparatus base 101 are a sheet feeding mechanism 11 including a plurality of rotary rollers or the like and a stage 20 that has a circular mounting surface 200 for mounting a sheet 12 on which to drop a liquid resin and is formed by a transparent member such as glass. The sheet feeding mechanism 11 formed by the plurality of rollers or the like can feed the sheet 12 of a desired length in a +Y direction from a sheet roll 129 formed by rolling the sheet 12 in a roll shape.

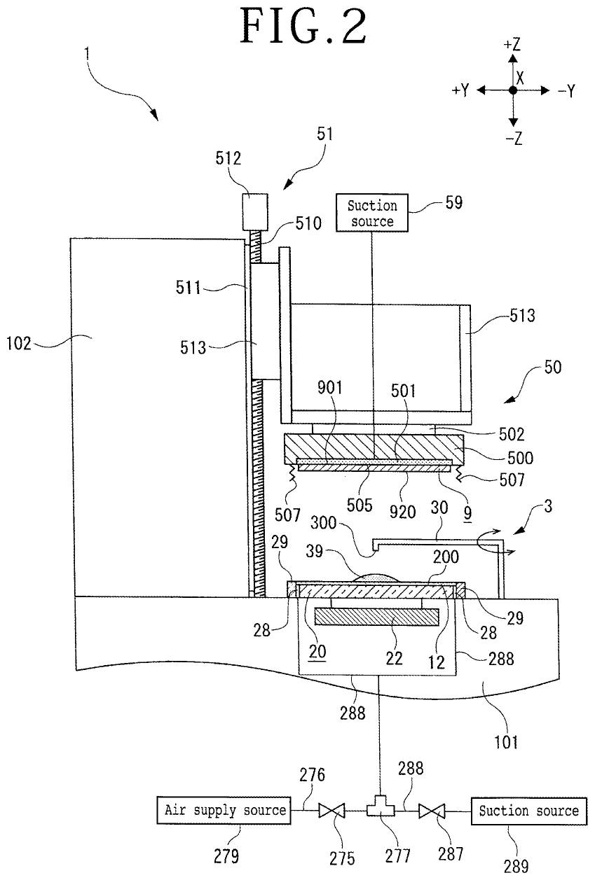

As illustrated in FIG. 2, the stage 20 is, for example, formed in a disk shape by quartz glass. The stage 20 has a flat specular mounting surface 200 having a larger area than the area of the one surface 920 of the workpiece 9 on which surface the protective member is to be formed. The sheet 12 having an area larger than that of the mounting surface 200 is mounted on the mounting surface 200. The stage 20 is supported by a cylindrical frame body 29 having a circular recessed portion.

An annular suction port 28 is formed between the outer surface of the stage 20 and the inner surface of the frame body 29. As illustrated in FIG. 2, the suction port 28 disposed annularly on the outside of the mounting surface 200 and communicating with a suction source 289 such as a vacuum generating apparatus via a pipe 288 generates a vacuum between the lower surface of the sheet 12 mounted on the mounting surface 200 and the mounting surface 200, and holds the lower surface of the sheet 12 under suction. The pipe 288 is, for example, provided with a suction valve 287. The suction valve 287 can switch between a communicating state and a non-communicating state between the suction source 289 and the suction port 28.

The pipe 288 communicates with one end of an air supply pipe 276 through a three-way tube 277. An air supply source 279 such as a compressor communicates with another end of the air supply pipe 276. The air supply pipe 276 is provided with an opening and closing valve 275 such as a solenoid valve. The opening and closing valve 275 can switch between a communicating state and a non-communicating state between the air supply source 279 and the suction port 28.

Disposed in a position below the stage 20 is a curing unit 22 that cures a liquid resin spread by the workpiece 9 lowered above the sheet 12 mounted on the mounting surface 200 by applying an external stimulus to the liquid resin to form the protective member in a plate shape. The curing unit 22, for example, includes ultraviolet (UV) lamps capable of applying ultraviolet rays of a predetermined wavelength in an upward direction. Incidentally, in a case where the liquid resin supplied onto the sheet 12 by a liquid resin supply unit 3 is a thermosetting resin, the curing unit 22 may be a heater or the like.

A sheet mounting mechanism 21 that mounts the sheet 12 onto the stage 20 is disposed on the supporting base 103 illustrated in FIG. 1. The sheet mounting mechanism 21 includes an arm portion 210 horizontally extending in the X-axis direction and capable of reciprocating in the Y-axis direction and a clamp portion 211 attached to a side surface of the arm portion 210. The clamp portion 211 can clamp one end of the sheet 12 of the sheet roll 129, pull out the sheet 12 in the Y-axis direction, and mount the sheet 12 onto the mounting surface 200 of the stage 20.

The sheet 12 pulled out onto the mounting surface 200 of the stage 20 is, for example, cut by a cutter not illustrated.

Disposed in the vicinity of the stage 20 is the liquid resin supply unit 3 that can supply a predetermined amount of liquid resin onto the upper surface of the sheet 12 held under suction on the mounting surface 200 of the stage 20. The liquid resin supply unit 3 includes a resin supply nozzle 30, a dispenser 31 that sends out a predetermined amount of liquid resin to the resin supply nozzle 30, and a connecting pipe 32 that connects the resin supply nozzle 30 and the dispenser 31 to each other. The resin supply nozzle 30 has a supply port 300 facing the mounting surface 200 of the stage 20. The resin supply nozzle 30 is swingable about an axis in a Z-axis direction, and can thereby move the supply port 300 from above the stage 20 to a retracted position. The dispenser 31 is connected to a resin supply source not illustrated. The liquid resin supplied by the liquid resin supply unit 3 is an ultraviolet curing resin cured by being irradiated with an ultraviolet ray in the present embodiment, but may be a thermosetting resin cured by applying heat thereto. In addition, a main component of the liquid resin is polyvinyl chloride in the present embodiment, but is not limited to this.

Disposed on a front surface in a −Y direction side of the column 102 illustrated in FIG. 1 is an expanding mechanism 51 that makes the holding unit 50 and the stage 20 relatively approach each other in a direction perpendicular to the mounting surface 200 (Z-axis direction), and thereby spreads the liquid resin supplied to the upper surface of the sheet 12 by the one surface 920 as the lower surface of the workpiece 9 held by the holding unit 50.

The expanding mechanism 51 includes a ball screw 510 having an axis in the Z-axis direction (vertical direction), a pair of guide rails 511 arranged in parallel with the ball screw 510, a motor 512 that is coupled to the ball screw 510 and rotates the ball screw 510, and a raising and lowering holder 513 that has an internal nut screwed onto the ball screw 510 and has side portions in sliding contact with the guide rails 511. The expanding mechanism 51 is configured such that as the motor 512 rotates the ball screw 510, the raising and lowering holder 513 is raised or lowered together with the supported holding unit 50 while guided by the guide rails 511.

The holding unit 50 that holds the workpiece 9 illustrated in FIGS. 2 and 3 includes a wheel supporting unit 502 held by the raising and lowering holder 513, a disk-shaped wheel 500 fixed to the lower end side of the wheel supporting unit 502, and a holding portion 501 that is formed by a porous member or the like, is supported by the wheel 500, and holds the workpiece 9 under suction. The circular plate-shaped holding portion 501 illustrated in FIG. 2 is, for example, fitted into the lower surface side of the wheel 500, and communicates with a suction source 59 such as a vacuum generating apparatus. A suction force produced by suction of the suction source 59 is transmitted to a flat suction surface 505, which is an exposed surface of the holding portion 501 and faces the mounting surface 200 of the stage 20. The holding unit 50 can thereby hold the workpiece 9 under suction by the suction surface 505.

Incidentally, FIG. 2 illustrates the workpiece 9 in a simplified manner.

As illustrated in FIG. 2, for example, a tubular bellows cover 507 that can be expanded and contracted in the Z-axis direction is disposed on a region on an outer circumferential side of the lower surface of the wheel 500 so as to surround the suction surface 505. The lower end side of the bellows cover 507 in an extended state can be made to abut against and fixed to the upper surface of the frame body 29, for example. Incidentally, the arrangement position of the bellows cover 507 is not limited to the illustrated example, nor is the position to which the lower end of the bellows cover 507 is fixed limited to the upper surface of the frame body 29.

In the following, description will be made of operation of the protective member forming apparatus 1 and a role of the sheet 12 in a case where the protective member is formed on the workpiece 9 by performing a protective member forming method according to the present invention by using the above-described protective member forming apparatus 1 and the sheet 12 illustrated in detail in FIG. 3.

First, the first wafer transporting mechanism 1081 illustrated in FIG. 1 extracts the workpiece 9 before the formation of the protective member from the cassette 1043, and transports the workpiece 9 onto the first support 1051. After the wafer detecting unit 106 detects the central position or the like of the workpiece 9, the second wafer transporting mechanism 1090 unloads the workpiece 9 from the first support 1051 in a state of holding the workpiece 9 under suction by the holding hand, moves to the −Y direction side, and transfers the workpiece 9 to the holding unit 50.

As illustrated in FIGS. 2 and 3, in a state in which the center of the suction surface 505 of the holding portion 501 and the center of the workpiece 9 are made to substantially coincide with each other, the holding unit 50 holds the other surface 901 of the workpiece 9 under suction by the suction surface 505. Next, the holding under suction of the one surface 920 of the workpiece 9 by the holding hand of the second wafer transporting mechanism 1090 is released, and the second wafer transporting mechanism 1090 retracts from below the workpiece 9.

### (1) Sheet Mounting Step

In parallel with the transportation of the workpiece 9 to the holding unit 50, the clamp portion 211 of the sheet mounting mechanism 21 illustrated in FIG. 1 clamps the sheet 12 and moves to the +Y direction side, thereby extracts a predetermined length of sheet 12 from the sheet roll 129, and mounts the sheet 12 onto the mounting surface 200 of the stage 20. Then, the suction source 289 is actuated in a state in which the suction valve 287 illustrated in FIG. 2 is opened. A suction force generated by the suction source 289 is transmitted to the mounting surface 200 through the pipe 288 and the suction port 28. A vacuum atmosphere is thereby produced between the lower surface of the sheet 12 and the mounting surface 200, so that the sheet 12 is held under suction on the mounting surface 200 and closely adheres to the mounting surface 200.

Thereafter, for example, a cutter not illustrated cuts the sheet 12 in a band shape into a circular shape having a slightly larger diameter than the workpiece 9.

Incidentally, the sheet 12 in a band shape may be cut into a predetermined length, and the cut sheet 12 may be transported to the mounting surface 200 and be held under suction on the mounting surface 200.

As illustrated in FIG. 3, the above-described sheet 12 according to the present invention which sheet is used in the protective member forming apparatus 1 includes a first layer 121 brought into contact with the mounting surface 200 and a second layer 122 brought into contact with a resin 39 supplied to the sheet 12 from the liquid resin supply unit 3 illustrated in FIG. 2. As compared with the second layer 122, the first layer 121 is formed of a material that is easily separated from the mounting surface 200 when the workpiece 9 provided with the protective member is lifted by air by jetting the air from the annular suction port 28 illustrated in FIG. 2 after the protective member is formed, that is, after the first layer 121 closely adheres to the mounting surface 200. For example, the first layer 121 is formed by a polyethylene terephthalate sheet that has a certain degree of hardness as a resin and is not easily softened by heat of reaction at a time of curing of the resin 39. Incidentally, the first layer 121 may be formed by a polyamide sheet or a polyimide sheet.

As compared with the first layer 121, the second layer 122 is formed of a material having high adhesiveness to the resin 39 cured on the second layer 122. In the present embodiment, for example, the resin 39 is formed with polyvinyl chloride as a main component, and therefore a polyolefin-based resin sheet is used as the second layer 122. Specifically, for example, the second layer 122 is formed by a resin sheet such as a polyethylene sheet, a polypropylene sheet, or a polystyrene sheet.

The first layer 121 and the second layer 122 are, for example, compression-bonded and integrated with each other by superposing the first layer 121 and the second layer 122 on each other in advance, and heating the first layer 121 and the second layer 122 to a temperature in the vicinity of a melting point while pressing both layers by applying a predetermined pressure.

### (2) Resin Supply Step

Next, the resin supply nozzle 30 of the liquid resin supply unit 3 illustrated in FIGS. 1 and 2 makes a swinging movement, so that the supply port 300 is positioned above the central region of the sheet 12 on the mounting surface 200. Next, the dispenser 31 illustrated in FIG. 1 feeds a predetermined amount of liquid resin 39 whose temperature is managed at a reference temperature to the resin supply nozzle 30. As illustrated in FIGS. 2 and 3, the liquid resin 39 is dropped from the supply port 300 to the upper surface formed by the second layer 122 of the sheet 12 held under suction on the stage 20. Then, after a predetermined amount of liquid resin 39 is accumulated on the sheet 12, the supply of the liquid resin 39 to the sheet 12 by the liquid resin supply unit 3 is stopped, and the resin supply nozzle 30 makes a swinging movement and retracts from above the mounting surface 200.

### (3) Protective Member Forming Step

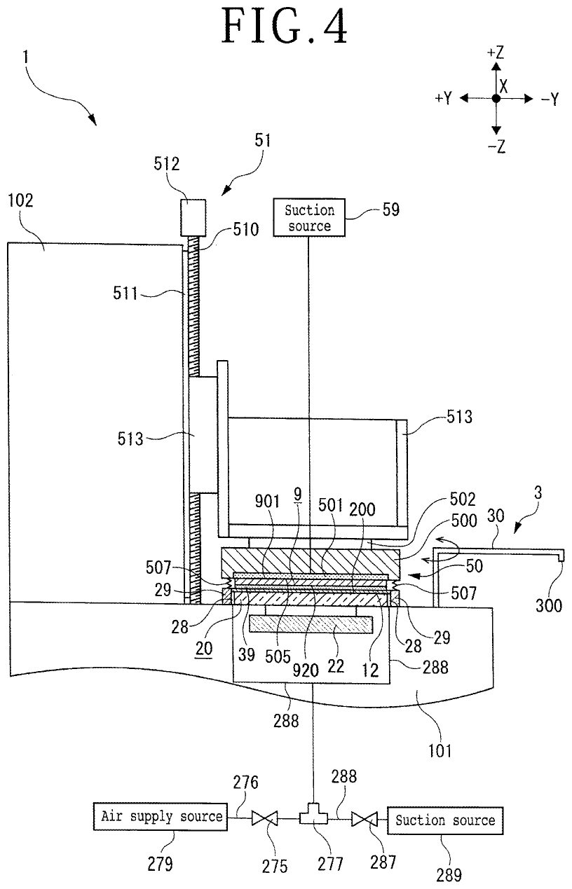

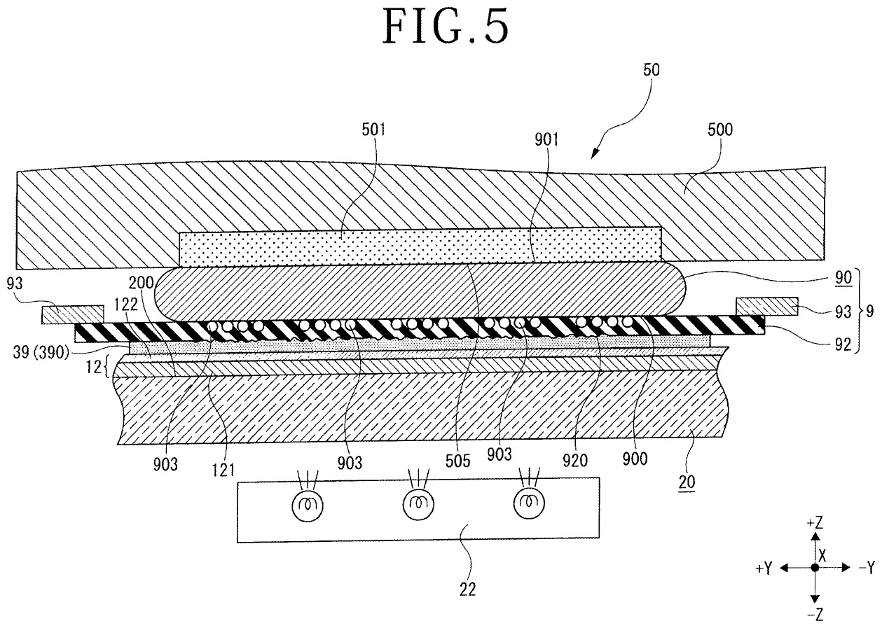

After the resin supply step is performed, the expanding mechanism 51 illustrated in FIG. 2 lowers the holding unit 50 in a state in which the holding unit 50 holds the other surface 901 of the workpiece 9 under suction by the suction surface 505. Then, as illustrated in FIG. 4 and FIG. 5, the one surface 920 of the workpiece 9 held under suction by the holding unit 50 comes into contact with the liquid resin 39. When the holding unit 50 is further lowered, the liquid resin 39 pressed by the one surface 920 of the workpiece 9 is spread in a radial direction of the workpiece 9. As a result, a film of the liquid resin 39 illustrated in FIGS. 4 and 5 is formed over a wide area of the one surface 920 of the workpiece 9. The film of the liquid resin 39 accommodates projections and depressions corresponding to the bumps 903 on the one surface 920 of the tape 92, and the lower surface of the film of the liquid resin 39 becomes a flat surface.

As described above, while the resin 39 is spread over the one surface 920 as the lower surface of the workpiece 9 by pressing the workpiece 9 onto the liquid resin 39 supplied to the upper surface formed by the second layer 122 of the sheet 12, a lower end of the bellows cover 507 is fixed to the upper surface of the frame body 29 as illustrated in FIG. 4, and the mounting surface 200 and the sheet 12 are thereby surrounded, so that a space sealed by the holding unit 50, the bellows cover 507, and the frame body 29 is formed. Then, because suction by the suction source 289 is continued, a state closer to a vacuum is created between the lower surface of the sheet 12 and the mounting surface 200, and thus the lower surface of the sheet 12 and the mounting surface 200 closely adhere to each other, so that the holding under suction of the sheet 12 on the mounting surface 200 is performed more securely. In addition, because the workpiece 9 presses the sheet 12 in a direction of the mounting surface 200, an air slightly remaining between the sheet 12 and the mounting surface 200 is expelled outward in the radial direction of the sheet 12 and is sucked by the suction port 28.

After the workpiece 9 is pressed against the liquid resin 39 for a predetermined time, and the film of the liquid resin 39 is formed over a wide area of the one surface 920 of the workpiece 9, the curing unit 22 illustrated in FIGS. 4 and 5 irradiates the film of the liquid resin 39 with ultraviolet rays as an external stimulus. As a result, the film of the liquid resin 39 to which the external stimulus is applied is cured, and formed as a plate-shaped protective member 390 having a predetermined thickness on the one surface 920 of the workpiece 9. The protective member 390 is bonded and fixed to the one surface 920 of the workpiece 9 and the upper surface of the sheet 12.

After the protective member 390 is formed as described above, the workpiece 9 is separated from the stage 20 together with the sheet 12. Specifically, the suction valve 287 illustrated in FIG. 4 is closed, and thereby the transmission of the suction force produced by the suction source 289 to the suction port 28 is interrupted. Further, air is supplied from the air supply source 279 to the air supply pipe 276 in a state in which the opening and closing valve 275 is opened. The air is jetted upward from the suction port 28. A jetting pressure of this air lifts the sheet 12 from the mounting surface 200, eliminates a vacuum suction force remaining between the mounting surface 200 and the sheet 12, and thus surely detaches the workpiece 9, the protective member 390, and the sheet 12 from the stage 20.

In the detachment of the workpiece 9 on which the protective member 390 is formed from the stage 20, even when the sheet 12 is heated by a heat of reaction at a time of curing of the liquid resin 39 by the curing unit 22 as illustrated in FIG. 4 and FIG. 5 described earlier, the first layer 121 illustrated in FIG. 5 in the sheet 12 which layer is in contact with the mounting surface 200 of the stage 20 is formed of a material that is not easily softened by the heat of reaction and maintains a certain degree of hardness, the material being, for example, polyethylene terephthalate or the like, and therefore when the jetting pressure of the air jetted upward from the suction port 28 lifts an outer circumferential portion of the sheet 12, not only the outer circumferential portion but also the center of the sheet 12 is lifted. Thus, separation from the stage 20 is facilitated, so that work efficiency is improved. In addition, as compared with the first layer 121, the second layer 122 is formed of a material having high adhesiveness to the cured resin 39. Thus, the sheet 12 is not peeled off from the formed protective member 390.

The workpiece 9 on which the protective member 390 is formed is transported to the second support 1052 by the second wafer transporting mechanism 1090 illustrated in FIG. 1. The cutter 107 cuts an excess of the sheet 12, the protective member 390, and the tape 92 into a circular shape along the outer circumferential edge of the wafer 90. The workpiece 9 is then housed into the cassette 1044 by the first wafer transporting mechanism 1081.

Thereafter, the workpiece 9 is mounted on a holding surface of a chuck table of a grinding apparatus not illustrated such that the other surface 901 on which the protective member 390 is not formed is on an upper side. A rotating grinding wheel is then lowered from above the workpiece 9. The workpiece 9 is ground while a grinding stone is made to abut against the other surface 901 of the workpiece 9. A tape peeling apparatus thereafter peels the protective member 390 off from the workpiece 9. Next, the one surface 920 of the workpiece 9 protected by the protective member 390 is further ground. The workpiece 9 having both surfaces as flat surfaces is thereby manufactured.

It is needless to say that the method of forming the sheet and the protective member according to the present invention is not limited to the foregoing embodiment, but may be carried out in various different forms within the scope of the technical concept of the present invention. In addition, the shape or the like of each configuration of the protective member forming apparatus 1 illustrated in the accompanying drawings is not limited thereto either, but can be modified as appropriate within a range in which effects of the present invention can be exerted.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A sheet used at a time of formation of a protective member protecting one surface of a plate-shaped workpiece by spreading and curing a liquid resin on the one surface, the sheet comprising:
a first layer configured to be brought into contact with a flat specular mounting surface; and
a second layer configured to be brought into contact with the liquid resin,
the first layer being formed of a material that is easily separated from the mounting surface after adhering to the mounting surface as compared with the second layer,
the second layer being formed of a material having high adhesiveness to the cured resin as compared with the first layer.

2. The sheet according to claim 1, wherein
the first layer is formed of polyethylene terephthalate, polyamide, or polyimide.

3. A protective member forming method using a sheet to form the protective member protecting one surface of a plate-shaped workpiece, the sheet used at a time of formation of the protective member protecting the one surface of the plate-shaped workpiece by spreading and curing a liquid resin on the one surface, the sheet including
a first layer configured to be brought into contact with a flat specular mounting surface, and
a second layer configured to be brought into contact with the liquid resin,
the first layer being formed of a material that is easily separated from the mounting surface after adhering to the mounting surface as compared with the second layer,
the second layer being formed of a material having high adhesiveness to the cured resin as compared with the first layer,
the protective member forming method comprising:
a sheet mounting step of mounting the sheet onto the mounting surface such that the first layer is in contact with the mounting surface;
a resin supply step of supplying the liquid resin to the second layer side of the sheet; and
a protective member forming step of bonding and fixing the protective member in a plate shape, the protective member being formed by the resin in a cured state, to the one surface of the workpiece and the second layer of the sheet by curing the liquid resin after spreading the resin over the one surface of the workpiece by pressing the workpiece against the liquid resin supplied to the sheet.

4. The protective member forming method according to claim 3, wherein
the first layer is formed of polyethylene terephthalate, polyamide, or polyimide.
